(19) United States
(12) Patent Application Publication
(10) Pub. No.: US 2008/0230114 A1
(43) Pub. Date: Sep. 25, 2008

(54) SOLAR CELL MODULE

(75) Inventors: Shihomi Nakatani, Kaizuka City (JP); Yasuo Kadonaga, Kaizuka City (JP); Yousuke Ishii, Kaizuka City (JP); Masaru Hikosaka, Izumisano City (JP); Shingo Okamoto, Toyonaka City (JP)

Correspondence Address: MOTS LAW, PLLC, 1001 PENNSYLVANIA AVE. N.W., SOUTH, SUITE 600, WASHINGTON, DC, 20004, US

(73) Assignee: SANYO ELECTRIC CO., LTD., Moriguchi City (JP)

(21) Appl. No.: 12/045,866

(22) Filed: Mar. 11, 2008

(30) Foreign Application Priority Data
Mar. 20, 2007 (JP) JP2007-073550

(51) Int. Cl. H01L 31/00

(52) U.S. Cl. 136/252

(57) ABSTRACT

Disclosed is a solar cell module that reduces entering of moisture into a solar cell module from a side surface SF thereof, and has high moisture-resistant properties. The disclosed solar cell module is a solar cell module in which solar cells 13a to 13d are sealed by a sealing member 21 between a transparent front surface protective member 11 and a back surface protective member 12, wherein the sealing member 21 includes at least a first sealing member 14 and a second sealing member 15, the first sealing member and the second sealing member are different in type, and the sealing member 21 exposed to a side surface SF of the solar cell module is the first sealing member 14.

### CROSS REFERENCE TO RELATED APPLICATIONS

This application is based upon and claims the benefit of priority from prior Japanese Patent Application No. 2007-073550, filed on Mar. 20, 2007; the entire contents of which are incorporated herein by reference.

### BACKGROUND OF THE INVENTION

1. Field of the Invention

The present invention relates to a semiconductor device that responds to an infrared ray, visible light and a short electromagnetic wave, and particularly, to a solar cell module that converts radiation energy thereof into electric energy.

2. Description of the Related Art

A solar cell can directly convert the sunbeam, which is a clean and unlimited energy source, into electricity, and accordingly, has attracted attention as a new energy source that is environment-friendly.

In the case of using such a solar cell as a power source (the energy source), it is common to use the solar cell in a form of a solar cell module of which output is enhanced by serially or parallely connecting a plurality of solar cells. The solar cell module is formed by electrically connecting connection electrodes of the plurality of solar cells to one another by a wiring member made of a conductive material such as copper foil, and by sealing the plurality of solar cells by a transparent sealing member such as ethylene vinyl acetate (EVA) between a transparent front surface protective member such as glass or transparent plastics and a back surface protective member made of a film of polyethylene terephthalate (PET) or the like.

The wiring member is arranged on one main surface of the solar cell. Therefore, it is desired to ensure electrical insulation between the wiring member and the front surface protective member and between the wiring member and the back surface protective member. For this, a technique to arrange two or more sealing members different in type between one surface protective member and the solar cell has been known (Japanese Patent Laid-Open No. 2006-278740). In this technique, by arranging a first sealing member on the one surface protective member side and arranging a second sealing member of which a softening point is lower than a softening point of the first sealing member on the solar cells side, the distance between the wiring member and the one surface protective member can be maintained more than the thickness of the first sealing member. Accordingly, the electrical insulation between the wiring member and the one surface protective member can be ensured.

### BRIEF SUMMARY OF THE INVENTION

A feature of the present invention is a solar cell module in which a solar cell is sealed by a sealing member between a transparent front surface protective member and a back surface protective member, wherein the sealing member includes at least a first sealing member and a second sealing member, the first sealing member and the second sealing member are different in type, and the sealing member exposed to a side surface of the solar cell module is the first sealing member.

In the feature of the present invention, the first sealing member may contact an outer circumference of the front surface protective member and an outer circumference of the back surface protective member.

In the feature of the present invention, the first sealing member and the second sealing member may be laminated at least either between the front surface protective member and the solar cell or between the solar cell and the back surface protective member.

In the feature of the present invention, a softening point of the second sealing member may be lower than a softening point of the first sealing member, and that the second sealing member may contact at least either a main surface of the solar cell on the front surface protective member side or a main surface of the solar cell on the back surface protective member side.

In the feature of the present invention, the sealing member that contacts the front surface protective member and the back surface protective member may be the first sealing member, and that the first sealing member be composed of an ethylene vinyl acetate copolymer (EVA).

### BRIEF DESCRIPTION OF THE SEVERAL VIEWS OF THE DRAWINGS

FIG. 1A is a cross-sectional view showing a configuration of a solar cell module according to a first embodiment of the present invention.

FIG. 1B is a schematic view for explaining a method for manufacturing the solar cell module of FIG. 1A.

FIG. 2A is a cross-sectional view showing a configuration of a solar cell module according to a second embodiment of the present invention.

FIG. 2B is a schematic view for explaining a method for manufacturing the solar cell module of FIG. 2A.

FIG. 3A is a cross-sectional view showing a configuration of a solar cell module according to a third embodiment of the present invention.

FIG. 3B is a schematic view for explaining a method for manufacturing the solar cell module of FIG. 3A.

FIG. 4A is a cross-sectional view showing a configuration of a solar cell module according to a fourth embodiment of the present invention.

FIG. 4B is a schematic view for explaining a method for manufacturing the solar cell module of FIG. 4A.

FIG. 5A is a cross-sectional view showing a configuration of a solar cell module according to a fifth embodiment of the present invention.

FIG. 5B is a schematic view for explaining a method for manufacturing the solar cell module of FIG. 5A.

### DETAILED DESCRIPTION OF THE INVENTION

A description will be made below of embodiments of the present invention with reference to the drawings. In the description of the drawings, the same reference numerals are assigned to the same portions.

### First Embodiment

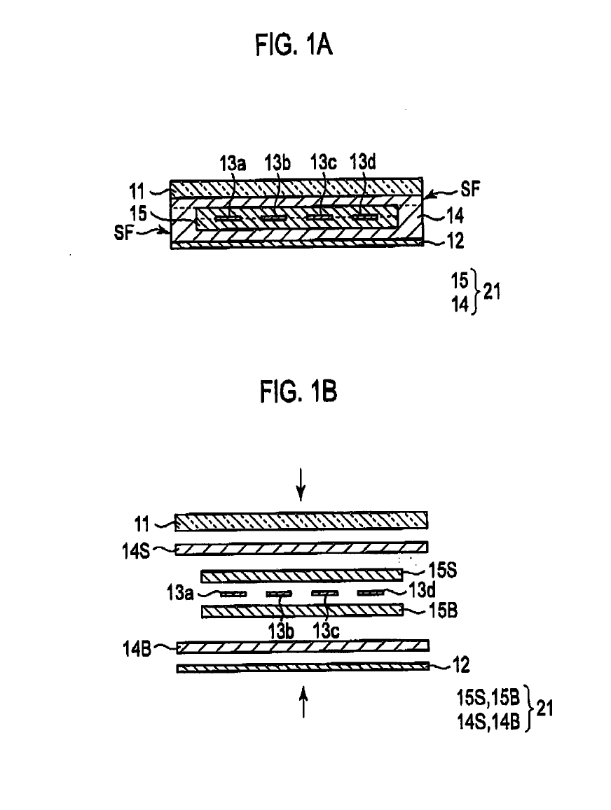

A description will be made of a configuration of a solar cell module according to a first embodiment of the present invention with reference to FIG. 1A.

The solar cell module includes a plurality (for example, four) of solar cells 13a, 13b, 13c and 13d. Each of the solar cells 13a to 13d includes a photoelectric conversion part (not shown in FIG. 1A) that generates photogenerated carriers by light made incident thereonto, and a pair of positive and negative electrodes (not shown in FIG. 1A) for taking out the photogenerated carriers generated in the photoelectric conversion part. The plurality of solar cells 13a to 13d are electrically connected to one another in series or parallel, by connecting electrodes included in each of the solar cells each other by use of wiring member. Copper foil of which a surface is subjected to tin plating may be used as the wiring member. The plurality of solar cells 13a to 13d are sealed by a sealing member 21 between a front surface protective member 11 and a back surface protective member 12. Glass or transparent plastics may be used as the front surface protective member 11. A film of PET and the like, or a laminated material in which a thin metal film of Al and the like is sandwiched between films of the PET and the like may be used as the back surface protective member 12.

The sealing member 21 includes at least a first sealing member 14 and a second sealing member 15. The first sealing member 14 and the second sealing member 15 are different in type. Specifically, as the sealing member 21, two or more sealing members different in type are used.

Here, the sealing members different in type refer to sealing members in which at least principal chains are different. Moreover, to a side surface SF of the solar cell module, the front surface protective member 11, the sealing member 21 and the back surface protective member 12 are exposed. Among sealing members included in the sealing member 21, a sealing member exposed to the side surface SF of the solar cell module is the first sealing member 14. One or more sealing members other than the first sealing member 14 among the sealing members included in the sealing member 21, for example the second sealing member 15 and the like, are not exposed to the side surface SF of the solar cell module. Specifically, the sealing member exposed to the side surface SF of the solar cell module is only one type of the sealing member. Note that the side surface SF of the solar cell module is shown as a surface exposed to the outside.

The first sealing member 14 and the second sealing member 15 are laminated at least either between the front surface protective member 11 and the solar cells 13a to 13d or between the solar cells 13a to 13d and the back surface protective member 12. In the first embodiment, a description will be made of the case where the first sealing member 14 and the second sealing member 15 are laminated both between the front surface protective member 11 and the solar cells 13a to 13d and between the solar cells 13a to 13d and the back surface protective member 12. In particular, one layer of the first sealing member 14 and one layer of the second sealing member 15 are laminated between the front surface protective member 11 and the solar cells 13a to 13d, in the first embodiment. Between the front surface protective member 11 and the solar cells 13a to 13d, the first sealing member 14 is disposed on the front surface protective member 11 side, and the second sealing member 15 is disposed on the solar cells 13a to 13d side. In a similar way, one layer of the second sealing member 15 and one layer of the first sealing member 14 are laminated between the solar cells 13a to 13d and the back surface protective member 12, in the first embodiment. Between the solar cells 13a to 13d and the back surface protective member 12, the second sealing member 15 is disposed on the solar cells 13a to 13d side, and the first sealing member 14 is disposed on the back surface protective member 12 side. Note that at least one layer of the first sealing member 14 and at least one layer of the second sealing member 15 just need to be laminated, and two or more layers of the first sealing member 14 or the second sealing member 15 may be laminated. For example, the second sealing member 15, the first sealing member 14 and the second sealing member 15 may be laminated in this order between the front surface protective member 11 and the solar cells 13a to 13d.

A material that composes the second sealing member 15 is different from a material that composes the first sealing member 14. Moreover, the second sealing member 15 contacts at least either main surfaces (first main surfaces) of the solar cells 13a to 13d on the front surface protective member 11 side or main surfaces (second main surfaces) of the solar cells 13a to 13d on the back surface protective member 12 side. In the first embodiment, a description will be made of the case where the second sealing member 15 contacts both of the first main surfaces and second main surfaces of the solar cells 13a to 13d. Moreover, the second sealing member 15 also contacts side surfaces of the solar cells 13a to 13d. Note that each of the side surfaces of the solar cells 13a to 13d contacts the first main surfaces and the second main surfaces. The second sealing member 15 is disposed so as to surround each of the solar cells 13a to 13d. Hence, there is no portion where the first sealing member 14 and the solar cells 13a to 13d contact each other. Furthermore, the second sealing member 15 is also disposed in gaps among the solar cells 13a to 13d adjacent to one another, and the one second sealing member 15 surrounds the entirety of the plurality of solar cells 13a to 13d.

The first sealing member 14 contacts at least either the front surface protective member 11 or the back surface protective member 12. Moreover, on a plane view of the solar cell module, the second sealing member 15 is disposed in a region including the solar cells 13a to 13d, and has an area smaller than the front surface protective member 11 and the back surface protective member 12 have. Moreover, the first sealing member 14 is also disposed in a region that is located on the same plane as the second sealing member 15 and surrounds the second sealing member 15. Hence, the second sealing member 15 that surrounds the solar cells 13a to 13d is embedded in the first sealing member 14, and the front surface protective member 11 and the back surface protective member 12 are adhered onto each other by the first sealing member 14. As the first sealing member 14, it is preferable to use an ethylene vinyl acetate copolymer (EVA) excellent in adhesion properties with the glass and a resin film.

In the first embodiment, a description will be made of the case where a sealing member, among sealing members included in the sealing member 21, that contacts the front surface protective member 11 and the back surface protective member 12 is the first sealing member 14, and the second sealing member 15 does not contact either the front surface protective member 11 or the back surface protective member 12. As the sealing member (the second sealing member 15) different in type from the EVA (the first sealing member 14), silicon resin, polyvinyl chloride, polyvinyl butyral (PVB), polyurethane, and the like are mentioned. These materials are composed so as to have different polymer, or are composed so as to have principal chains, side chains, functional groups, which are partially different from each other, and the like. Features of the respective materials are as follows. The silicon resin is a little inferior in weatherability to the other materials. The polyvinyl chloride is more prone to be affected by temperature and has larger elasticity than the other materials. Although the PVB is superior in ultraviolet resistance to the other materials, the PVB is inferior in shrinkage properties and water resistance. Although the polyurethane is superior in weatherability to the other materials, the polyurethane has larger elasticity.

A description will be made of a method for manufacturing the solar cell module of FIG. 1A with reference to FIG. 1B.

(A) First, a laminated body is formed by laminating a first sealing member 14S, a second sealing member 15S, the plurality of solar cells 13a to 13d connected to one another by the wiring member, a second sealing member 15B, a first sealing member 14B and the back surface protective member 12 on the front surface protective member 11 sequentially. As the front surface protective member 11, glass or transparent plastics is used. As the first sealing member 14S and the first sealing member 14B, the sheet-like EVA are used. As the second sealing member 15S and the second sealing member 15B, the sheet-like PVB are used. As the back surface protective member 12, the film of the PET and the like are used. At this time, on a plane view of the solar cell module, outer circumferences of the second sealing members 15S and 15B are located inside of outer circumferences of the first sealing members 14S and 14B. Moreover, the first main surfaces and the second main surfaces of the plurality of solar cells 13a to 13d are sandwiched between the second sealing members 15S and 15B. Moreover, on a plane view of the solar cell module, the plurality of solar cells 13a to 13d are located inside of the outer circumferences of the second sealing members 15S and 15B. An outer dimension of the front surface protective member 11 and the back surface protective member 12 is substantially equal to an outer dimension of the first sealing members 14S and 14B. Note that, as the back surface protective member 12, one having a three-layer structure of the PET, aluminum foil and the PET may be used.

(B) Then, the laminated body is disposed in a decompression chamber, and the decompression chamber is evacuated. Thereafter, the laminated body is heated and pressed at 150° C. for 10 minutes, whereby the front surface protective member 11, the first sealing member 14S, the second sealing member 15S, the plurality of solar cells 13a to 13d, the second sealing member 15B, the first sealing member 14B and the back surface protective member 12 included in the laminated body are temporarily adhered with each other. Thereafter, the laminated body is heated at 150° C. for one hour, whereby the sealing member 21, which is including the first sealing member 14S, the second sealing member 15S, the second sealing member 15B and the first sealing member 14B, is completely crosslinked. By the above-described steps, the solar cell module shown in FIG. 1A is completed. Thereafter, a terminal box and a metal frame may be attached onto the solar cell module according to needs.

In accordance with the first embodiment of the present invention, which is as described above, the following functions and effects are obtained.

When the two or more sealing members different in type (the first sealing member 14 and the second sealing member 15) are used as the sealing member 21 that seals the solar cells 13a to 13d between the transparent front surface protective member 11 and the back surface protective member 12, the interface between the different types of sealing members are sometimes exposed to the side surface SF of the solar cell module. Here, moisture is more prone to enter the solar cell module from an interface between the different types of sealing members than from an interface between same types of sealing members. Hence, in the case where the interface between the different types of sealing members are exposed to the side surface SF of the solar cell module, adhesion properties between the solar cells 13a to 13d and the sealing members (the first sealing member 14 and the second sealing member 15) may be decreased due to entering of the moisture from the interface between the different types of sealing members exposed to the side surface of the solar cell module. Consequently, it is apprehended that moisture-resistant properties of the solar cell module may be decreased.

In this connection, when the two or more sealing members (the first sealing member 14 and the second sealing member 15) different in type are used as the sealing member 21, one (the first sealing member 14) of the sealing members is adapted to be exposed to the side surface SF of the solar cell module, in the first embodiment of the present invention. In such a way, the interface between the different types of sealing members is avoided being exposed to the side surface SF of the solar cell module. Accordingly, the entering of the moisture from the interface between the different types of sealing members is reduced, and the adhesion properties between the solar cells 13a to 13d and the sealing members (the first sealing member 14 and the second sealing member 15) is enhanced. Consequently, the and the moisture-resistant properties of the solar cell module is enhanced.

Moreover, the first sealing member 14 and the second sealing member 15 are laminated at least either between the front surface protective member 11 and the solar cells 13a to 13d or between the solar cells 13a to 13d and the back surface protective member 12. At this time, the first sealing member 14 is arranged on the one surface protective member side (the front surface protective member 11 side or the back surface protective member 12 side), and the second sealing member 15 is arranged on the solar cells 13a to 13d side. Here, the softening point of the first sealing member 14 and the softening point of the second sealing member 15 are differentiated by differentiating materials composing the first sealing member 14 and the second sealing member 15 respectively.

For example, a Vicat softening temperature of the EVA, which may be used as the first sealing member 14, is approximately 40° C. On the other hand, a Vicat softening temperature of the PVB, which may be used as the second sealing member 15, is 70 to 120° C.

That is to say, the softening point of the second sealing member 15 is lower than the softening point of the first sealing member 14. Hence, the distance between the wiring member and the one surface protective member (the front surface protective member 11 or the back surface protective member 12) can be maintained more than the thickness of the first sealing member 14, because the thickness of the first sealing member 14 is unchanged. Accordingly, the electrical insulation between the wiring member and the front surface protective member or the back surface protective member can be ensured. Furthermore, when the laminated body is heated and pressed, it is possible to avoid concentration of the pressure on the wiring member and to average the pressure added to each part of the solar cells 13a to 13d, because the second sealing member 15 which has lower softening point is arranged on the solar cells 13a to 13d side.

Moreover, for example, the first sealing member 14 made of the EVA and the second sealing member 15 made of the PVB excellent in ultraviolet resistance are laminated between the solar cells 13a to 13d and the front surface protective member 11, whereby a solar cell module excellent in ultraviolet resistance can be provided.

Among sealing members included in the sealing member 21, a sealing member that contacts the front surface protective member 11 and the back surface protective member 12 is the first sealing member 14. Moreover, the first sealing member 14 is composed of the ethylene vinyl acetate copolymer (EVA). Here, the ethylene vinyl acetate copolymer has strong adhesion force with the front surface protective member 11 and with the back surface protective member 12. Accordingly, the adhesion properties between the sealing member 21 and the front surface protective member 11 and the back surface protective member 12 are enhanced, and peeling becomes less likely to occur therebetween.

### Second Embodiment

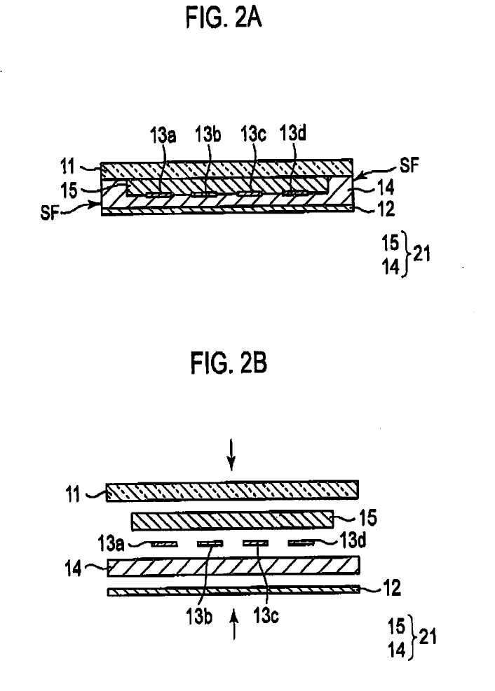

A description will be made of a configuration of a solar cell module according to a second embodiment of the present invention with reference to FIG. 2A.

In a similar way to the first embodiment, the solar cell module according to the second embodiment includes the plurality of solar cells 13a, 13b, 13c and 13d connected in series or parallel by the wiring member, the transparent front surface protective member 11, the back surface protective member 12, and the transparent sealing member 21 that seals the plurality of solar cells 13a to 13d. In the second embodiment, the sealing member 21 includes the first sealing member 14 and the second sealing member 15. The first sealing member 14 and the second sealing member 15 are different in type. Specifically, as the sealing member 21, two or more sealing members different in type are used. Moreover, to a side surface SF of the solar cell module, the front surface protective member 11, the sealing member 21 and the back surface protective member 12 are exposed. Among sealing members included in the sealing member 21, a sealing member exposed to the side surface SF of the solar cell module is the first sealing member 14, and the second sealing member 15 is not exposed to the side surface SF of the solar cell module.

In the second embodiment, only the second sealing member 15 is disposed between the front surface protective member 11 and the solar cells 13a to 13d, and only the first sealing member 14 is disposed between the solar cells 13a to 13d and the back surface protective member 12. Specifically, though a piece of the sealing member 21 disposed between the front surface protective member 11 and the solar cells 13a to 13d and a piece of the sealing member 21 disposed between the solar cells 13a to 13d and the back surface protective member 12 are different in type from each other, each piece of the sealing member 21 has a single layer structure.

The second sealing member 15 contacts the first main surfaces of the solar cells 13a to 13d. The first sealing member 14 contacts the second main surfaces of the solar cells 13a to 13d. Both of the first sealing member 14 and the second sealing member 15 included in the sealing member 21 contact the front surface protective member 11. The first sealing member 14 contacts an outer circumferential portion of the front surface protective member 11, and the second sealing member 15 contacts a portion (a center portion) of the front surface protective member 11, which excludes the outer circumferential portion thereof. The first sealing member 14 contacts the back surface protective member 12, and the second sealing member 15 does not contact the back surface protective member 12.

Other configurations are the same as the solar cell module of FIG. 1A, and accordingly, a description thereof will be omitted.

A description will be made of a method for manufacturing the solar cell module of FIG. 2A with reference to FIG. 2B.

(A) First, a laminated body is formed by laminating a second sealing member 15, the plurality of solar cells 13a to 13d connected to one another by the wiring member, a first sealing member 14 and the back surface protective member 12 on the front surface protective member 11 sequentially. As the front surface protective member 11, glass or transparent plastics is used. As the second sealing member 15, the sheet-like PVB is used. As the first sealing member 14, the sheet-like EVA is used. As the back surface protective member 12, the film of the PET and the like are used. At this time, on a plane view of the solar cell module, outer circumferences of the second sealing member 15 are located inside of outer circumferences of the first sealing member 14. Moreover, on a plane view of the solar cell module, the plurality of solar cells 13a to 13d are located inside of the outer circumferences of the second sealing member 15. An outer dimension of the front surface protective member 11 and the back surface protective member 12 is substantially equal to an outer dimension of the first sealing member 14.

(B) Then, the laminated body is disposed in a decompression chamber, and the decompression chamber is evacuated. Thereafter, the laminated body is heated and pressed at 150° C. for 10 minutes, whereby the front surface protective member 11, the second sealing member 15, the plurality of solar cells 13a to 13d, the first sealing member 14 and the back surface protective member 12 included in the laminated body are temporarily adhered with each other. Thereafter, the laminated body is heated at 150° C. for one hour, whereby the sealing member 21, which is including the first sealing member 14 and the second sealing member 15, is completely crosslinked. By the above-described steps, the solar cell module shown in FIG. 2A is completed. Thereafter, a terminal box and a metal frame may be attached onto the solar cell module according to needs.

### Third Embodiment

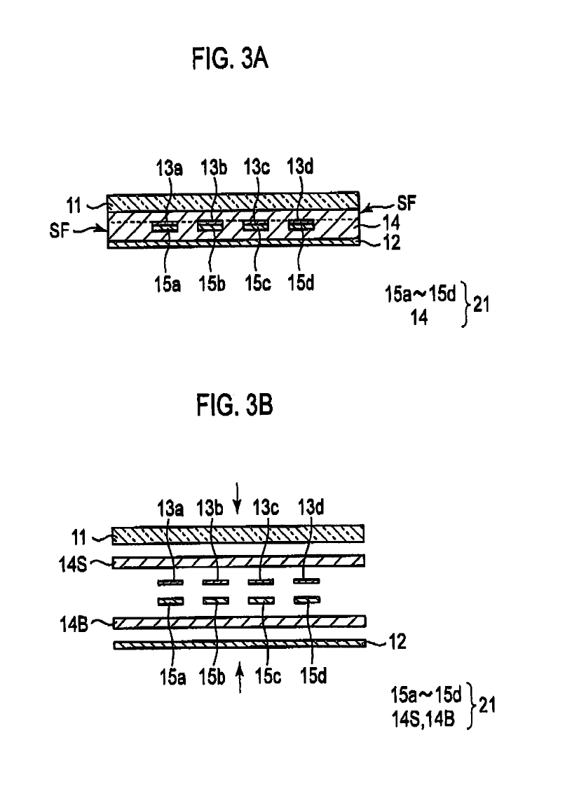

A description will be made of a configuration of a solar cell module according to a third embodiment of the present invention with reference to FIG. 3A.

In a similar way to the first embodiment, the solar cell module according to the third embodiment includes the plurality of solar cells 13a, 13b, 13c and 13d connected in series or parallel by the wiring member, the transparent front surface protective member 11, the back surface protective member 12, and the transparent sealing member 21 that seals the plurality of solar cells 13a to 13d. In the third embodiment, the sealing member 21 includes the first sealing member 14 and the second sealing members 15a, 15b, 15c and 15d. The first sealing member 14 and the second sealing members 15a to 15d are different in type. Specifically, as the sealing member 21, two or more sealing members different in type are used. Moreover, to a side surface SF of the solar cell module, the front surface protective member 11, the sealing member 21 and the back surface protective member 12 are exposed. Among sealing members included in the sealing member 21, a sealing member exposed to the side surface SF of the solar cell module is the first sealing member 14, and the second sealing members 15a to 15d is not exposed to the side surface SF of the solar cell module.

In the third embodiment, the first sealing member 14 and the second sealing members 15a to 15d are laminated between the solar cells 13a to 13d and the back surface protective member 12. Only the first sealing member 14 is disposed between the front surface protective member 11 and the solar cells 13a to 13d, and the first sealing member 14 forms a single layer structure.

The second sealing members 15a to 15d contact the second main surfaces of the solar cells 13a to 13d. Moreover, the second sealing members 15a to 15d are arranged separately from one another so as to correspond to the solar cells 13a to 13d, respectively. Hence, the first sealing member 14 is disposed in the gaps among the solar cells 13a to 13d adjacent to one another. The first sealing member 14 contacts the first main surfaces and side surfaces of the solar cells 13a to 13d. The first sealing member 14 contacts the front surface protective member 11 and the back surface protective member 12, and the second sealing member 15 does not contact either the front surface protective member 11 or the back surface protective member 12.

Other configurations are the same as the solar cell module of FIG. 1A, and accordingly, a description thereof will be omitted.

A description will be made of a method for manufacturing the solar cell module of FIG. 3A with reference to FIG. 3B.

(A) First, a laminated body is formed by laminating the first sealing member 14S, the plurality of solar cells 13a to 13d connected to one another by the wiring member, the second sealing members 15a to 15d, the first sealing member 14B and the back surface protective member 12 on the front surface protective member 11 sequentially. As the front surface protective member 11, glass or transparent plastics is used. As the first sealing member 14S and the first sealing member 14B, the sheet-like EVA are used. As the second sealing members 15a to 15d, the sheet-like PVB are used. As the back surface protective member 12, the film of the PET and the like are used. At this time, on a plane view of the solar cell module, outer circumferences of the second sealing members 15a to 15d are located inside of outer circumferences of the first sealing members 14S and 14B. Moreover, on a plane view of the solar cell module, an outer dimension of the plurality of solar cells 13a to 13d is substantially equal to an outer shape of the second sealing members 15a to 15d. The second sealing members 15a to 15d are arranged so as to be superposed on the solar cells 13a to 13d, respectively. An outer dimension of the front surface protective member 11 and the back surface protective member 12 is substantially equal to an outer dimension of the first sealing members 14S and 14B.

(B) Then, the laminated body is disposed in a decompression chamber, and the decompression chamber is evacuated. Thereafter, the laminated body is heated and pressed at 150° C. for 10 minutes, whereby the front surface protective member 11, the first sealing member 14S, the plurality of solar cells 13a to 13d, the second sealing members 15a to 15d, the first sealing member 14B and the back surface protective member 12 included in the laminated body are temporarily adhered with each other. Thereafter, the laminated body is heated at 150° C. for one hour, whereby the sealing member 21, which is including the first sealing member 14S, second sealing members 15a to 15d and the first sealing member 14B, is completely crosslinked. By the above-described steps, the solar cell module shown in FIG. 3A is completed. Thereafter, a terminal box and a metal frame may be attached onto the solar cell module according to needs.

### Fourth Embodiment

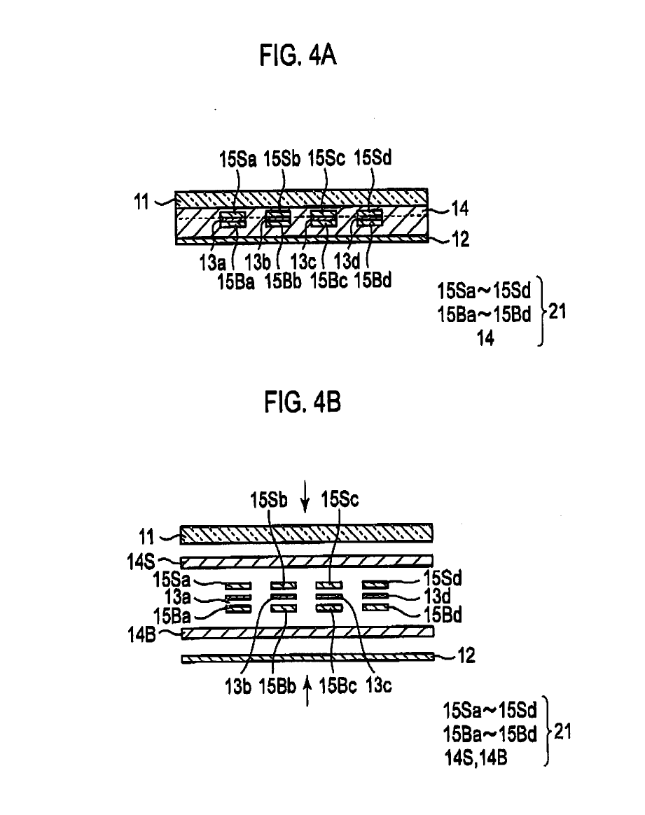

A description will be made of a configuration of a solar cell module according to a fourth embodiment of the present invention with reference to FIG. 4A.

In a similar way to the first embodiment, the solar cell module according to the fourth embodiment includes the plurality of solar cells 13a, 13b, 13c and 13d connected in series or parallel by the wiring member, the transparent front surface protective member 11, the back surface protective member 12, and the transparent sealing member 21 that seals the plurality of solar cells 13a to 13d. In the fourth embodiment, the sealing member 21 includes the first sealing member 14 and the second sealing members 15Sa, 15Sb, 15Sc and 15Sd, 15Ba, 15Bb, 15Bc and 15Bd. The first sealing member 14 and the second sealing members 15Sa to 15Sd and 15Ba to 15Bd are different in type. Specifically, as the sealing member 21, two or more sealing members different in type are used. Moreover, to a side surface SF of the solar cell module, the front surface protective member 11, the sealing member 21 and the back surface protective member 12 are exposed. Among sealing members included in the sealing member 21, a sealing member exposed to the side surface SF of the solar cell module is the first sealing member 14, and the second sealing members 15Sa to 15Sd and 15Ba to 15Bd are not exposed to the side surface SF of the solar cell module.

In the fourth embodiment, the first sealing member 14 and the second sealing members 15Sa to 15Sd and 15Ba to 15Bd are laminated both between the front surface protective member 11 and the solar cells 13a to 13d and between the solar cells 13a to 13d and the back surface protective member 12. In particular, one layer of the first sealing member 14 and one layer of each of the second sealing members 15Sa to 15Sd are laminated between the front surface protective member 11 and the solar cells 13a to 13d. Between the front surface protective member 11 and the solar cells 13a to 13d, the first sealing member 14 is disposed on the front surface protective member 11 side, and the second sealing members 15Sa to 15Sd are arranged on the solar cells 13a to 13d side. In a similar way, one layer of each of the second sealing members 15Ba to 15Bd and one layer of the first sealing member 14 are laminated between the solar cells 13a to 13d and the back surface protective member 12. Between the solar cells 13a to 13d and the back surface protective member 12, the second sealing members 15Sa to 15Sd are arranged on the solar cells 13a to 13d side, and the first sealing member 14 is disposed on the back surface protective member 12 side. Note that, though a description is made of the case where one layer of the first sealing member 14, one layer of each of the second sealing members 15Sa to 15Sd and one layer of each of the second sealing members 15Ba to 15Bd are laminated between the front surface protective member 11 and the solar cells 13a to 13d and between the solar cells 13a to 13d and the back surface protective member 12, two or more layers of the first sealing member 14 or the second sealing member 15 may be laminated. For example, the second sealing member 15, the first sealing member 15 and the second sealing member 15 may be laminated in this order between the front surface protective member 11 and the solar cells 13a to 13d.

The second sealing members 15Sa to 15Sd contact the first main surfaces of the solar cells 13a to 13d, and the second sealing members 15Ba to 15Bd contact the second main surfaces of the solar cells 13a to 13d. Moreover, the second sealing members 15Sa to 15Sd and 15Ba to 15Bd are arranged separately from one another so as to correspond to the solar cells 13a to 13d, respectively. Hence, the first sealing member 14 is disposed in the gaps among the solar cells 13a to 13d adjacent to one another, and the first sealing member 14 contacts the side surfaces of the solar cells 13a to 13d. The first sealing member 14 contacts the front surface protective member 11 and the back surface protective member 12, and the second sealing member 15 does not contact either the front surface protective member 11 or the back surface protective member 12.

Other configurations are the same as the solar cell module of FIG. 1A, and accordingly, a description thereof will be omitted.

A description will be made of a method for manufacturing the solar cell module of FIG. 4A with reference to FIG. 4B.

(A) First, a laminated body is formed by laminating the first sealing member 14S, the second sealing members 15Sa to 15Sd, the plurality of solar cells 13a to 13d connected to one another by the wiring member, the second sealing members 15Ba to 15Bd, the first sealing member 14B and the back surface protective member 12 on the front surface protective member 11 sequentially. As the front surface protective member 11, glass or transparent plastics is used. As the first sealing member 14S and the first sealing member 14B, the sheet-like EVA are used. As the second sealing members 15Sa to 15Sd and the second sealing members 15Ba to 15Bd, the sheet-like PVB are used. As the back surface protective member 12, the film of the PET and the like are used. At this time, on a plane view of the solar cell module, outer circumferences of the second sealing members 15Sa to 15Sd and 15Ba to 15Bd are located inside of outer circumferences of the first sealing members 14S and 14B. Moreover, on a plane view of the solar cell module, an outer dimension of the plurality of solar cells 13a to 13d is substantially equal to an outer shape of the second sealing members 15Sa to 15Sd and 15Ba to 15Bd. The plurality of solar cells 13a to 13d are sandwiched between the second sealing members 15Sa to 15Sd and 15Ba to 15Bd, respectively, and the second sealing members 15Sa to 15Sd, the solar cells 13a to 13d and the second sealing members 15Ba to 15Bd are arranged so as to be superposed on one another, respectively. The outer dimension of the front surface protective member 11 and the back surface protective member 12 is substantially equal to the outer dimension of the first sealing members 14S and 14B.

(B) Then, the laminated body is disposed in a decompression chamber, and the decompression chamber is evacuated. Thereafter, the laminated body is heated and pressed at 150° C. for 10 minutes, whereby the front surface protective member 11, the first sealing member 14S, the second sealing members 15Sa to 15Sd, the plurality of solar cells 13a to 13d, the second sealing members 15Ba to 15Bd, the first sealing member 14B and the back surface protective member 12 included in the laminated body are temporarily adhered with each other. Thereafter, the laminated body is heated at 150° C. for one hour, whereby the sealing member 21, which is including the first sealing member 14S and 14B, and second sealing members 15Sa to 15Sd and 15Ba to 15Bd, is completely crosslinked. By the above-described steps, the solar cell module shown in FIG. 4A is completed. Thereafter, a terminal box and a metal frame may be attached onto the solar cell module according to needs.

### Fifth Embodiment

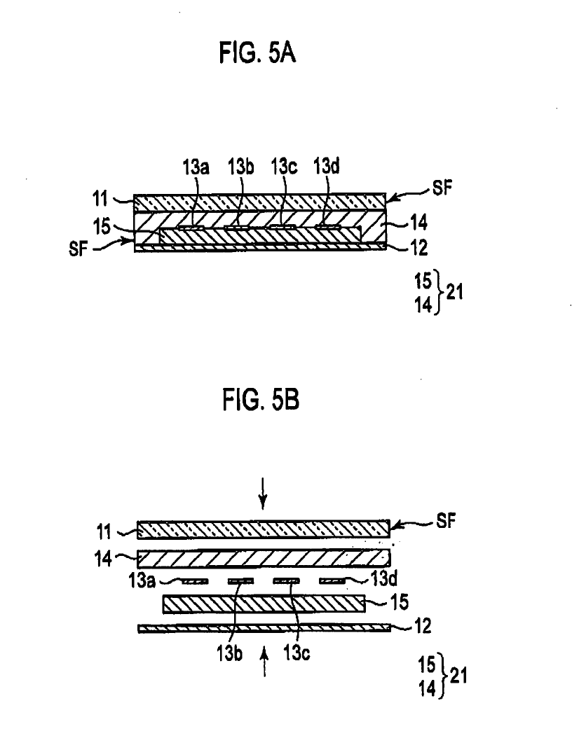

A description will be made of a configuration of a solar cell module according to a fifth embodiment of the present invention with reference to FIG. 5A.

In a similar way to the first embodiment, the solar cell module according to the fifth embodiment includes the plurality of solar cells 13a, 13b, 13c and 13d connected in series or parallel by the wiring member, the transparent front surface protective member 11, the back surface protective member 12, and the transparent sealing member 21 that seals the plurality of solar cells 13a to 13d. In the fifth embodiment, the sealing member 21 includes the first sealing member 14 and the second sealing member 15. The first sealing member 14 and the second sealing member 15 are different in type. Specifically, as the sealing member 21, two or more sealing members different in type are used. Moreover, to a side surface SF of the solar cell module, the front surface protective member 11, the sealing member 21 and the back surface protective member 12 are exposed. Among sealing members included in the sealing member 21, a sealing member exposed to the side surface SF of the solar cell module is the first sealing member 14, and the second sealing members 15Sa to 15Sd and 15Ba to 15Bd are not exposed to the side surface SF of the solar cell module.

In the fifth embodiment, only the first sealing member 14 is disposed between the front surface protective member 11 and the solar cells 13a to 13d, and only the second sealing member 15 is disposed between the solar cells 13a to 13d and the back surface protective member 12. Specifically, though a piece of the sealing member 21 disposed between the front surface protective member 11 and the solar cells 13a to 13d and a piece of the sealing member 21 disposed between the solar cells 13a to 13d and the back surface protective member 12 are different in type from each other, each piece of the sealing member 21 has a single layer structure.

The first sealing member 14 contacts the first main surfaces of the solar cells 13a to 13d. The second sealing member 15 contacts the second main surfaces of the solar cells 13a to 13d. Both of the first sealing member 14 and the second sealing member 15 included in the sealing member 21 contact the back surface protective member 12. The first sealing member 14 contacts an outer circumferential portion of the back surface protective member 12, and the second sealing member 15 contacts a portion (a center portion) of the back surface protective member 12, which excludes the outer circumferential portion thereof. The first sealing member 14 contacts the front surface protective member 11, and the second sealing member 15 does not contact the front surface protective member 11.

Other configurations are the same as the solar cell module of FIG. 1A, and accordingly, a description thereof will be omitted.

A description will be made of a method for manufacturing the solar cell module of FIG. 5A with reference to FIG. 5B.

(A) First, a laminated body is formed by laminating a first sealing member 14, the plurality of solar cells 13a to 13d connected to one another by the wiring member, a second sealing member 15 and the back surface protective member 12 on the front surface protective member 11 sequentially. As the front surface protective member 11, glass or transparent plastics is used. As the first sealing member 14, the sheet-like EVA is used. As the second sealing member 15, the sheet-like PVB is used. As the back surface protective member 12, the film of the PET and the like are used. At this time, on a plane view of the solar cell module, outer circumferences of the second sealing member 15 are located inside of outer circumferences of the first sealing member 14. Moreover, on a plane view of the solar cell module, the plurality of solar cells 13a to 13d are located inside of the outer circumferences of the second sealing member 15. An outer dimension of the front surface protective member 11 and the back surface protective member 12 is substantially equal to an outer dimension of the first sealing member 14.

(B) Then, the laminated body is disposed in a decompression chamber, and the decompression chamber is evacuated. Thereafter, the laminated body is heated and pressed at 150° C. for 10 minutes, whereby the front surface protective member 11, the first sealing member 14, the plurality of solar cells 13a to 13d, the second sealing member 15 and the back surface protective member 12 included in the laminated body are temporarily adhered with each other. Thereafter, the laminated body is heated at 150° C. for one hour, whereby the sealing member 21, which is including the first sealing member 14 and the second sealing member 15, is completely crosslinked. By the above-described steps, the solar cell module shown in FIG. 5A is completed. Thereafter, a terminal box and a metal frame may be attached onto the solar cell module according to needs.

### Other Embodiments

Although the present invention has been described as above by the five embodiments, it should not be understood that the description and the drawings, which form a part of this disclosure, limit the present invention. From this disclosure, a variety of alternative embodiments, examples and operation technologies will be obvious for those skilled in the art.

Although the description has been made of the case where the types of sealing members are two in the first to fifth embodiments of the present invention, it is a matter of course that the types may be three or more. Although the description has been made of the case where the ethylene vinyl acetate copolymer (EVA) is used as the first sealing member 14, the present invention is not limited to this, and a sealing member different in type from the EVA, for example, silicon resin, polyvinyl chloride, PVB, polyurethane and the like may be used as the first sealing member 14. In this case, a sealing member different in type from the first sealing member 14 may be used as the second sealing member 15.

It should be understood that the present invention incorporates a variety of embodiments and the like, which are not described herein, as described above. Hence, the present invention is to be limited only by items which specify the invention in accordance with the scope of claims reasonable from this disclosure.

What is claimed is:

1. A solar cell module in which a solar cell is sealed by a sealing member between a transparent front surface protective member and a back surface protective member, wherein
the sealing member includes at least a first sealing member and a second sealing member,
the first sealing member and the second sealing member are different in type, and
the sealing member exposed to a side surface of the solar cell module is the first sealing member.

2. The solar cell module according to claim 1, wherein the first sealing member contacts an outer circumference of the front surface protective member and an outer circumference of the back surface protective member.

3. The solar cell module according to claim 1, wherein the first sealing member and the second sealing member are laminated at least either between the front surface protective member and the solar cell or between the solar cell and the back surface protective member.

4. The solar cell module according to claim 3, wherein
a softening point of the second sealing member is lower than a softening point of the first sealing member, and
the second sealing member contacts at least either a main surface of the solar cell on the front surface protective member side or a main surface of the solar cell on the back surface protective member side.

5. The solar cell module according to any one of claims 1 to 4, wherein
the sealing member that contacts the front surface protective member and the back surface protective member is the first sealing member, and
the first sealing member is composed of an ethylene vinyl acetate copolymer (EVA).
